(19) United States
(12) Patent Application Publication
(10) Pub. No.: US 2023/0378315 A1
(43) Pub. Date: Nov. 23, 2023

(54) MANUFACTURING METHOD OF SEMICONDUCTOR DEVICE

(71) Applicant: Samsung Electronics Co., Ltd., Suwon-si (KR)

(72) Inventors: Myoungsoo Kim, Suwon-si (KR); Seongheon Woo, Suwon-si (KR); Youngchan Lee, Suwon-si (KR); Jungmin Hyun, Suwon-si (KR)

(21) Appl. No.: 18/060,037

(22) Filed: Nov. 30, 2022

(30) Foreign Application Priority Data
May 20, 2022 (KR) 10-2022-0062184

(51) Int. Cl. H01L 29/66; H01L 21/265; H01L 21/266

(52) U.S. Cl. CPC H01L 29/66492; H01L 21/26586; H01L 21/266

(57) ABSTRACT

A manufacturing method of a semiconductor device including forming a photoresist pattern on a semiconductor substrate on which a gate electrode has been formed, forming a well region using both the photoresist pattern and the gate electrode as a mask, forming a lightly doped drain (LDD) region in the well region, using both the photoresist pattern and the gate electrode as a mask, reducing a thickness of the photoresist pattern by removing a portion of the photoresist pattern, forming a halo region below the LDD region using both the photoresist pattern and the gate electrode as a mask, and removing the photoresist pattern.

### CROSS-REFERENCE TO RELATED APPLICATION(S)

This application claims benefit of priority to Korean Patent Application No. 10-2022-0062184 filed on May 20, 2022 in the Korean Intellectual Property Office, the disclosure of which is incorporated herein by reference in its entirety.

### BACKGROUND

The present inventive concept relates to a manufacturing method of a semiconductor device.

A semiconductor device is used in many electronic industries due to characteristics such as miniaturization, multifunctionality, and/or low manufacturing costs. The semiconductor device may include a memory device for storing data, a logic device for processing data, and a hybrid device capable of simultaneously performing various functions.

As the electronic industry is highly developed, demand for high integration of semiconductor devices is increasing. Accordingly, various problems, such as a decrease in a process margin of an exposure process for defining fine patterns, may occur, making it increasingly difficult to implement a semiconductor device. In addition, with the development of the electronics industry, demand for lowering the cost of semiconductor devices is also increasing. To this end, in order to reduce the manufacturing costs of semiconductor devices, various studies are being conducted.

### SUMMARY

Some embodiments of the present inventive concept is to provide a manufacturing method of a semiconductor device having reduced manufacturing costs.

According to some embodiments of the present inventive concept, a manufacturing method of a semiconductor device is provided, the manufacturing method of a semiconductor device including forming a photoresist pattern to a first thickness on a semiconductor substrate on which a device isolation film and a gate electrode have been formed, forming a well region, by implanting first conductivity-type impurity ions into a front surface of the semiconductor substrate, forming a lightly doped drain (LDD) region, by implanting low-concentration second conductivity-type impurity ions in the well region using both the photoresist pattern and the gate electrode as a mask, reducing the photoresist pattern to a second thickness, by removing a portion of the photoresist pattern, forming a halo region below the LDD region, by implanting the low-concentration second conductivity-type impurity ions in the well region at an oblique angle with respect to the front surface of the semiconductor substrate, using the photoresist pattern that has been reduced to the second thickness and the gate electrode as a mask, and removing the photoresist pattern of the second thickness.

According to some embodiments of the present inventive concept, a manufacturing method of a semiconductor device is provided, the manufacturing method of a semiconductor device including forming a photoresist pattern on a semiconductor substrate on which a gate electrode has been formed, and forming a well region using the photoresist pattern and the gate electrode as a mask, forming a lightly doped drain (LDD) region in the well region, using the photoresist pattern and the gate electrode as a mask, reducing a thickness of the photoresist pattern, by removing a portion of the photoresist pattern, forming a halo region below the LDD region, using the photoresist pattern and the gate electrode as a mask, and removing the photoresist pattern.

According to some embodiments of the present inventive concept, a manufacturing method of a semiconductor device is provided, the manufacturing method of a semiconductor device, including forming a photoresist pattern to a first thickness on a semiconductor substrate on which a gate electrode has been formed, forming a well region by implanting first conductivity-type impurity ions using both the photoresist pattern and the gate electrode as a mask, forming a lightly doped drain (LDD) region by implanting second conductivity-type impurity ions to the well region using both the photoresist pattern and the gate electrode as the mask, reducing a thickness of the photoresist pattern to a second thickness, by removing a portion of the photoresist pattern, forming a halo region below the LDD region, by implanting the first conductivity-type impurity ions, using the photoresist pattern and the gate electrode as a mask, and removing the photoresist pattern, wherein the second thickness is 30% to 95% of the first thickness.

### BRIEF DESCRIPTION OF DRAWINGS

The above and other aspects, features, and advantages of the present inventive concept will be more clearly understood from the following detailed description, taken in conjunction with the accompanying drawings, in which:

FIGS. 1, 2, 3, 4, 5A, 5B, 5C, 6A, 6B, 6C, and 7 are views illustrating each process of a method of manufacturing a semiconductor according to example embodiments.

FIGS. 8 and 9 are diagrams for illustrating each process of a method of manufacturing a semiconductor according to example embodiments.

### DETAILED DESCRIPTION

Hereinafter, example embodiments of the present inventive concept will be described with reference to the accompanying drawings.

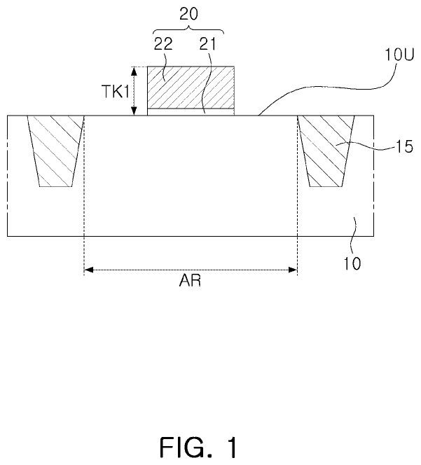

A manufacturing method of a semiconductor device according to an example embodiment will be described with reference to FIGS. 1 to 7.

Referring to FIG. 1, a device isolation film 15 and a gate electrode 20 may be formed on a front side 10U (or front surface) of a semiconductor substrate 10. For example, the semiconductor substrate 10 may include bulk-silicon or silicon-on-insulator (SOI). Alternatively, the semiconductor substrate 10 may be a silicon semiconductor substrate, or may include other materials such as silicon germanium (SiGe), indium antimonide (InSb), lead telluride, indium arsenide (InAs), indium phosphide (InP), gallium arsenide (GaAs), or gallium antimonide (GaSb). In addition, the semiconductor substrate 10 may have an epitaxial layer formed on a base semiconductor substrate.

The device isolation film 15 may define an active region AR in which a device is formed in a subsequent process. That is, the semiconductor substrate 10 may be divided into a field region in which the device isolation film 15 is formed and an active region in which the device isolation film 15 is not formed. The device isolation film 15 may be formed through a shallow trench isolation (STI) process, or the like, for example, by depositing an oxide film such as SiO₂.

The gate electrode 20 may be formed by laminating an insulating layer 21 and an electrode layer 22 on the active region AR and then patterning the insulating layer 21 and the electrode layer 22. The insulating layer 21 may include silicon oxide, and the electrode layer 22 may include polysilicon. A thickness TK1 of the gate electrode 20 may be formed to be thinner than a thickness of the photoresist pattern 40 formed in a subsequent process.

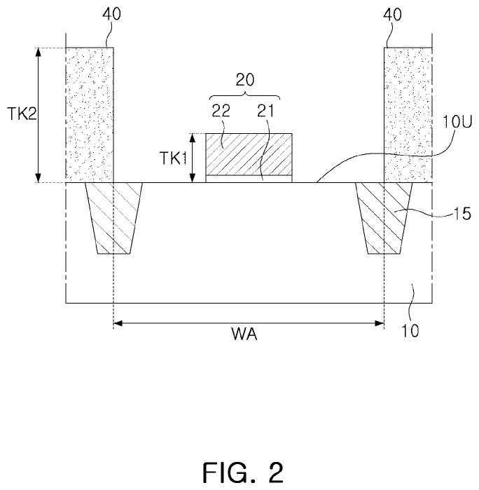

Next, referring to FIG. 2, a photoresist pattern 40 may be formed on the semiconductor substrate 10. The photoresist pattern 40 may be formed by depositing a photoresist layer on the semiconductor substrate 10, and then patterning the photoresist layer.

The photoresist pattern 40 may define a region WA in which a well region to be formed in a subsequent process will be formed. The first conductivity-type impurity ions implanted to form a well region may have a relatively high energy. In order to protect a field region of the semiconductor substrate 10 from the impurity ions having such high energy, a photoresist pattern 40 having a thick thickness TK2 may be formed. For example, the first thickness TK2 of the photoresist pattern 40 may be about 1.0 μm to 4.0 μm.

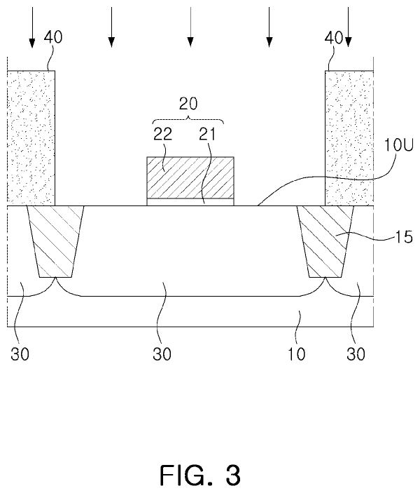

Next, referring to FIG. 3, a well region 30 may be formed by performing a process of implanting first conductivity-type impurity ions in a front side 10U of the semiconductor substrate 10 using a photoresist pattern 40 and a gate electrode 20 as a mask.

The well region 30 formed on the front side 10U of the semiconductor substrate 10 may be formed by, for example, implanting p-type impurity ions such as boron or aluminum. According to some embodiments, the well region 30 may be formed by implanting, for example, n-type impurity ions such as phosphorus or arsenic. The first conductivity-type impurity ions implanted in the well region 30 may be implanted at an incident angle of about 10° or less with respect to a normal direction of the front side 10U of the semiconductor substrate 10.

In example embodiments, the photoresist pattern 40 used as a mask for forming the well region 30 is recycled as a mask for a subsequent process of forming a lightly doped drain (LDD) region and a process of forming a halo region, a process of forming a separate mask may be omitted in each process. Accordingly, there may be an effect that a manufacturing time of the semiconductor device is shortened and manufacturing costs is reduced. Through this process, the well region 30 may be formed in a region in which the photoresist pattern 40 is opened, and the well region 30 formed below the photoresist pattern 40 may be formed through a separate process.

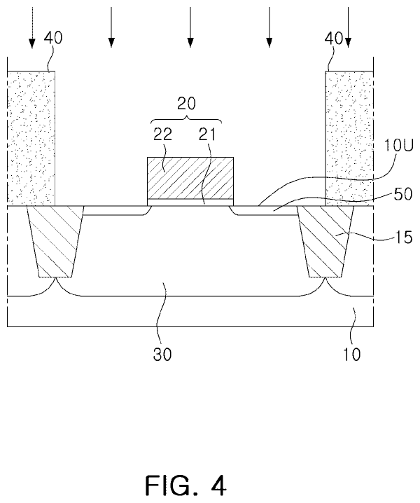

Next, referring to FIG. 4, an LDD region 50 may be formed on the well region 30.

The LDD region 50 may be formed by implanting low-concentration second conductivity-type impurity ions above the well region 30 using the gate electrode 20 and the photoresist pattern 40 as a mask. The second conductivity type impurity ions for forming the LDD region 50 may be implanted in a direction, normal to the front side 10U of the semiconductor substrate 10, and may have a polarity, different from that of the first conductivity-type impurity ions implanted to form the well region 30.

For example, when p-type impurity ions such as boron or aluminum are implanted in the well region 30, the LDD region 50 may be formed by implanting n-type impurity ions such as phosphorus, arsenic, or the like. On the other hand, when n-type impurity ions such as phosphorus, arsenic, or the like are implanted in the well region 30, the LDD region 50 may be formed by implanting p-type impurity ions such as boron, aluminum, or the like. The LDD region 50 may be formed by being self-aligned to the well region 30 by the gate electrode 20. A portion of the LDD region 50 may extend downwardly from the gate electrode 20 as the second conductivity-type impurity ions implanted in the LDD region 50 diffuse laterally. That is, a portion of the LDD region 50 may overlap the gate electrode 20.

As a semiconductor device is highly integrated, the size of the semiconductor device is decreased, but an operating voltage of the semiconductor device is not lowered enough to correspond to the decrease in the size of the semiconductor device. Accordingly, a very high electric field is concentrated on a portion of a drain region of the semiconductor device, and an undesired flow of carriers is formed, which may cause a problem that the semiconductor device may not operate normally. The LDD region 50 may control an electric field of carriers between the source region and the drain region, thereby preventing punch-through between the source region and the drain region and enhancing breakdown voltage characteristics.

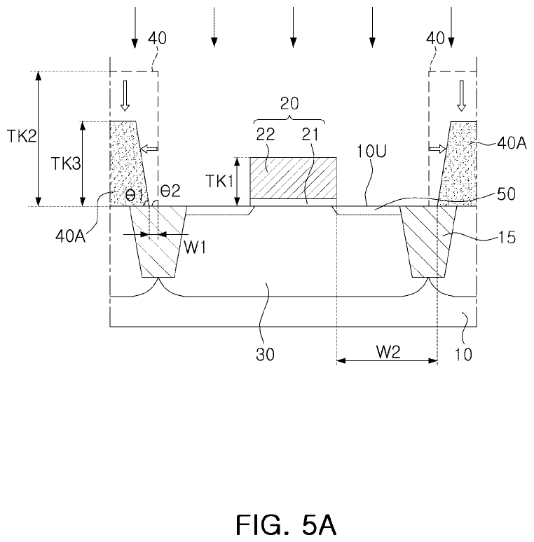

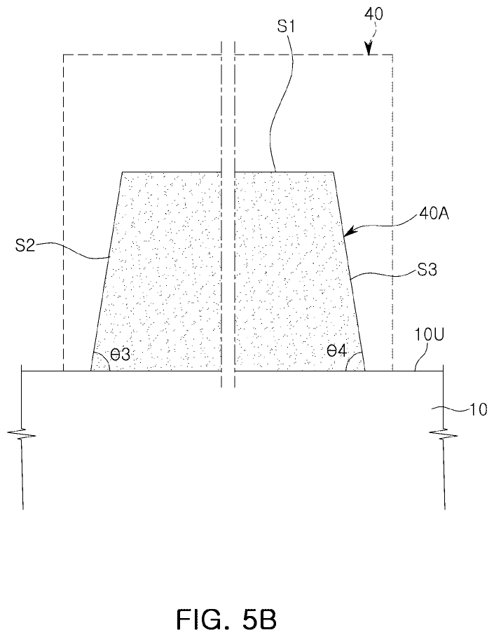

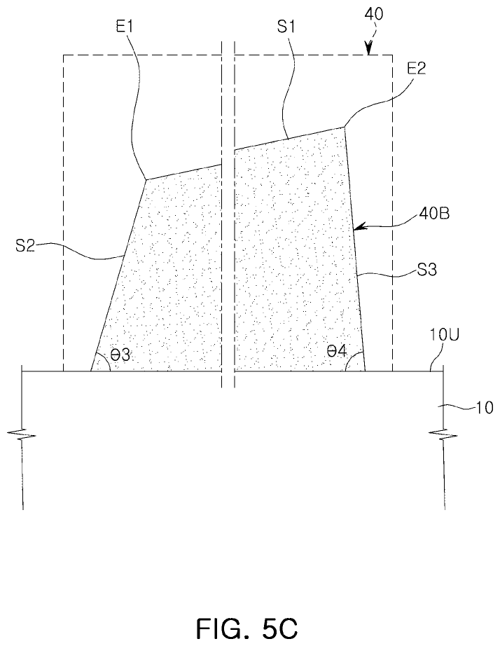

Next, referring to FIG. 5A, a thickness of the photoresist pattern 40 may be reduced. When an ashing process is applied to the photoresist pattern 40, the thickness of the photoresist pattern 40 may be reduced, and a temperature and/or time for which the ashing process is performed may be adjusted, to adjust a degree to which the thickness of the photoresist pattern 40 is reduced. Reference numeral 40 illustrates a photoresist pattern before the thickness is reduced, and reference numeral 40A illustrates a photoresist pattern having the reduced thickness.

The ashing process may include an oxygen (O₂) plasma treatment process or an ozone (O₃) treatment process. When an ashing process is applied to the photoresist pattern 40, the thickness of the photoresist pattern 40 may be reduced, so that the thickness thereof may be reduced from a first thickness TK2 to a second thickness TK3. The second thickness TK3 may be about 30% to 95% of the first thickness TK2. The second thickness TK3 may be thicker than the thickness TK1 of the gate electrode 20. In this process, a width of the photoresist pattern 40 may also be reduced by a first distance W1, so that a distance W2 between the gate electrode 20 and a sidewall of the photoresist pattern 40 may be increased. In addition, in some example embodiments, an inclined surface may be formed on a side surface of the photoresist pattern 40.

An inclination angle θ1 of a side surface of the photoresist pattern 40A after the ashing process is performed may be narrower than an inclination angle θ2 of a side surface of the photoresist pattern 40 before the ashing process is performed. In other words, the side surface of the photoresist pattern 40A after the ashing process is performed may have a gentle inclination surface compared to the side surface of the photoresist pattern 40 before the ashing process is performed. Accordingly, in a subsequent process of obliquely implanting impurity ions to form a halo region 60, an area of the region in which the impurity ions are implanted can be increased. This will be described later.

FIGS. 5B and 5C are diagrams schematically illustrating a cross-section of a photoresist pattern 40A having a reduced thickness.

Referring to FIG. 5B, a thickness of the photoresist pattern 40A on which an ashing process has been performed may be reduced so that level of an upper surface S1 may be lowered. In addition, according to example embodiments, side surfaces of the photoresist pattern 40A on which an ashing process is performed may be inclined surfaces having predetermined inclination angles θ3 and θ4 with respect to a front side 10U of the semiconductor substrate 10. The inclination angles θ3 and θ4 of each of the side surfaces S2 and S3 of the photoresist pattern 40A may be different from each other. However, according to example embodiments, an inclined surface may not be formed on the side surfaces S2 and S3 of the photoresist pattern 40A. In addition, although the upper surface S1 and the side surfaces S2 and S3 are illustrated as flat surfaces in FIG. 5B, an example embodiment thereof is not limited thereto, and according to the example embodiments, some regions may be formed in a curved surface.

In addition, according to example embodiments, as illustrated in FIG. 5C, an upper surface S1 of a photoresist pattern 40B on which an ashing process is performed may be an inclined surface. Accordingly, an edge E1 of one side surface S2 of the photoresist pattern 40B may have a different level from an edge E2 of the other side surface S3.

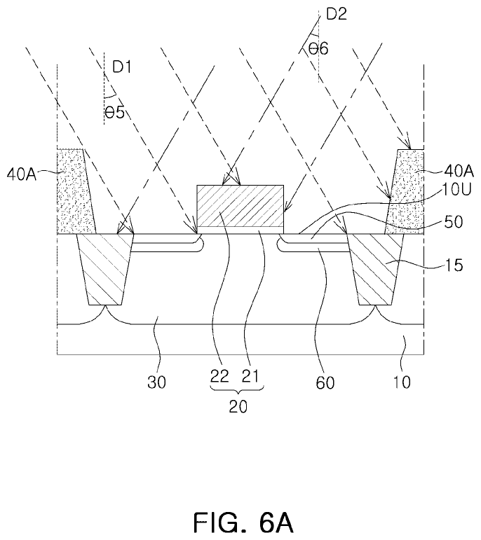

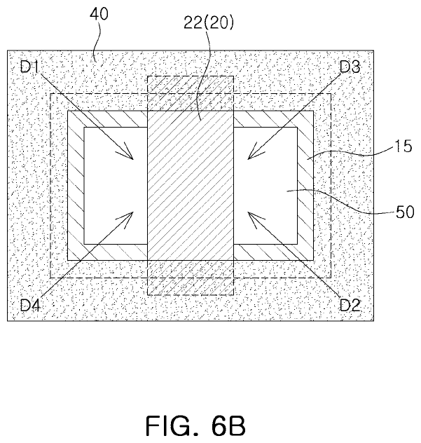

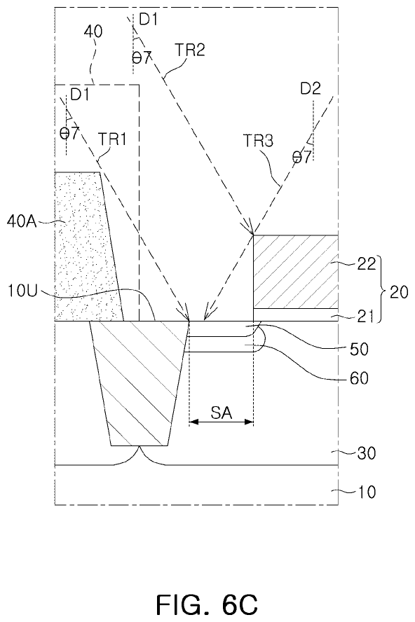

Next, referring to FIG. 6A, by using the photoresist pattern 40A having reduced thickness and the gate electrode 20 as a mask, low concentration of first conductivity-type impurity ions may be implanted therein in a direction, normal to the front side 10U of the semiconductor substrate 10, to form a halo region 60. For example, when n-type impurity ions such as phosphorus, arsenic, or the like, are implanted in the LDD region 50, the halo region 60 may be formed by implanting p-type impurity ions such as boron, aluminum, or the like. On the other hand, when p-type impurity ions such as boron, aluminum, or the like, are implanted in the LDD region 50, the halo region 60 may be formed by implanting n-type impurity ions such as phosphorus, arsenic, or the like.

The halo region 60 is used to improve Short Channel Effect (SCE) characteristics in which a threshold voltage is lowered due to a decrease in the length of a channel of a semiconductor device due to the LDD region 50, and may be formed below the LDD region 50. In addition, the first conductivity-type impurity ions for forming the halo region 60 may be implanted having predetermined inclination angles θ5 and 06 with respect to a normal direction, perpendicular to the front side 10U of the semiconductor substrate 10. The predetermined inclination angle may be about 25° to 50°. Accordingly, a portion of the halo region 60 may extend downwardly from the gate electrode 20. That is, a portion of the halo region 60 may overlap the gate electrode 20. In addition, referring to FIG. 6B, when viewed in a direction of the front side of the semiconductor substrate 10, the low-concentration first-conduction-type impurity ions for forming the halo region 60 may be implanted in four directions (D1, D2, D3, and D4), perpendicular to each other.

As described above, the first conductivity-type impurity ions implanted in the halo region 60 may be implanted therein at an inclination angle with respect to a normal direction of the front side 10U of the semiconductor substrate 10. As the semiconductor device becomes smaller, an interval between the photoresist pattern 40 and the gate electrode 20 may be also gradually reduced, so that there may be a problem in which the first conductivity-type impurity ions implanted therein at an inclination angle are blocked by the photoresist pattern 40. In example embodiments, by reducing the thickness of the photoresist pattern 40 in the previous process, the first conductivity-type impurity ions implanted therein at an inclination angle may be prevented from being blocked by the photoresist pattern 40. In this regard, it will be described with reference to FIG. 6C.

FIG. 6C illustrates trajectories TR1, TR2, and TR3 of the first conductivity—type impurity ions implanted therein while having a predetermined inclination angle θ7 in the D1 direction and the D2 direction. The first conductivity-type impurity ions implanted therein along the first trajectory TR1 and the third trajectory TR3 may not be blocked by the photoresist pattern 40A having a reduced thickness and may be implanted in the front side 10U of the semiconductor substrate 10. The first conductivity-type impurity ions implanted therein along the second trajectory TR2 may be blocked by the gate electrode 20. On the other hand, the first conductivity-type impurity ions implanted therein along the first trajectory TR1 and the third trajectory TR3 may be blocked by the photoresist pattern 40 a thickness of which is not reduced.

That is, among the first conductivity-type impurity ions implanted in the front side 10U of the semiconductor substrate 10, only a portion of first conductivity-type impurities implanted in the separation region SA between the gate electrode 20 and the device isolation film 15 may form the halo region 60. On the other hand, it can be seen that the first conductivity-type impurity ions implanted in a region, other than the separation region SA are blocked by the photoresist pattern 40A, that is, a shadowing effect is applied thereto.

Since the photoresist pattern 40 of which the thickness thereof is not reduced also blocks first conductivity-type impurity ions implanted therein in a first trajectory TR1 in a D1 direction, it can be seen that the shadowing effect is further increased. In order to solve this problem, it is necessary to increase a separation region SA, by modifying a design rule of the semiconductor device manufacturing process as a whole, but there may be a problem of going against the trend of miniaturization of the semiconductor device.

In other words, when all of the well region 30, the LDD region 50, and the halo region 60 are formed with one photoresist pattern, a manufacturing time may be shortened and manufacturing costs may reduce, but when a semiconductor device manufacturing process is performed by applying an existing design rule in a state in which the thickness of the photoresist pattern 40 is not reduced, there may be a problem in which the halo region 60 is not normally formed. According to example embodiments, by reducing the thickness of the photoresist pattern 40, the halo region 60 may be normally formed even when a semiconductor device manufacturing process is performed by applying an existing design rule.

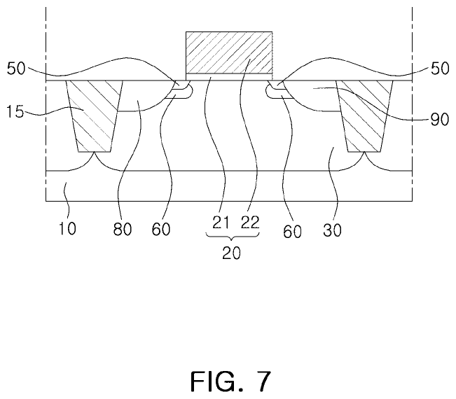

Next, referring to FIG. 7, the photoresist pattern 40 may be removed, and a high concentration of second conductivity type impurity ions may be implanted in the front side 10U of the semiconductor substrate 10 to form a source region 80 and a drain region 90. The photoresist pattern 40 may be removed in an ashing process and a stripping process. According to example embodiments, the ashing process and the stripping process may be sequentially performed. That is, after performing an ashing process of removing an upper portion of the photoresist pattern through an oxygen (O₂) plasma treatment process or an ozone (O₃) treatment process, the stripping process may be performed.

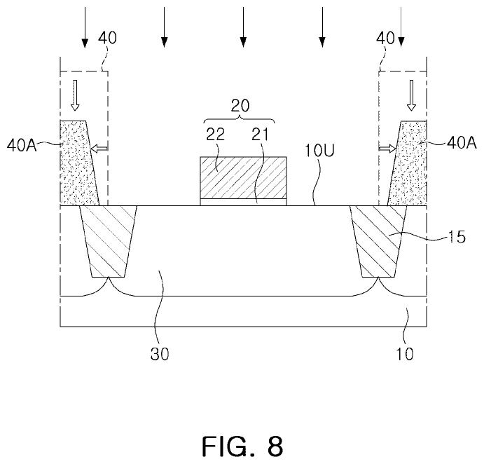

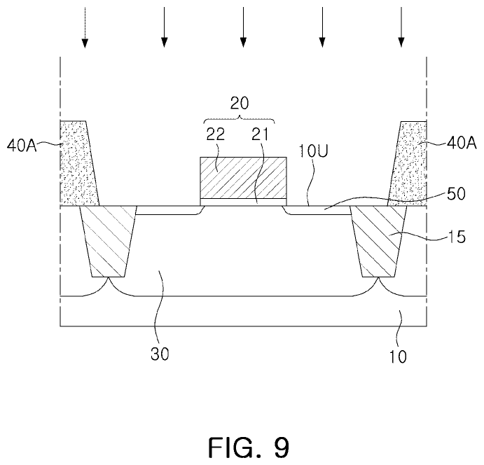

A manufacturing process of a semiconductor device according to example embodiments will be described with reference to FIGS. 8 and 9. Since the manufacturing process of a semiconductor device is a process in which an order of some processes of the above-described example embodiments, the changed process will mainly be described. A description of the process overlapping with the above-described example embodiments will be omitted.

The process illustrated in FIGS. 8 and 9 may be understood as a process subsequent to FIG. 3 of the above-described example embodiments. Referring to FIG. 8, a thickness of the photoresist pattern 40 may be reduced by applying an ashing process to the photoresist pattern 40. A specific method of reducing the thickness of the photoresist pattern 40 is the same as described above with reference to FIG. 5A.

Next, referring to FIG. 9, an LDD region 50 may be formed, using a photoresist pattern 40A having a reduced thickness, and a gate electrode 20. Since impurity ions for forming the LDD region 50 are implanted in a direction, normal to the front side 10U of the semiconductor substrate 10, the LDD region 50 may be formed regardless of the thickness of the photoresist pattern 40A. Since a method of forming the LDD region 50 is the same as that described above with respect to FIG. 4, a detailed description thereof will be omitted.

That is, in the example embodiments described above, after the process of forming a gate electrode and forming an LDD region (see FIG. 4), a process of reducing a thickness of a photoresist pattern (see FIG. 5A) is performed, but, in some example embodiments, after the process of reducing a thickness of a photoresist pattern (see FIG. 8), a process of forming an LDD region (see FIG. 9) is performed.

As set forth above, according to example embodiments of the present inventive concept, by replacing masks respectively formed, used in a plurality of manufacturing processes with one mask, manufacturing costs of the semiconductor device may be reduced.

Various and advantageous advantages and effects of the present inventive concept is not limited to the above description, it will be more readily understood in the process of describing the specific embodiments of the present inventive concept.

While the example embodiments have been shown and described above, it will be apparent to those skilled in the art that modifications and variations could be made without departing from the scope of the present inventive concept as defined by the appended claims.

What is claimed is:

1. A manufacturing method of a semiconductor device, the manufacturing method comprising:
forming a photoresist pattern to a first thickness on a semiconductor substrate on which a device isolation film and a gate electrode have been formed;
forming a well region by implanting first conductivity-type impurity ions into a front surface of the semiconductor substrate;
forming a lightly doped drain (LDD) region, by implanting low-concentration second conductivity-type impurity ions in the well region using both the photoresist pattern and the gate electrode as a mask;
reducing the photoresist pattern to a second thickness, by removing a portion of the photoresist pattern;
forming a halo region below the LDD region, by implanting the first conductivity-type impurity ions in the well region at an oblique angle with respect to the front surface of the semiconductor substrate, using the photoresist pattern that has been reduced to the second thickness and the gate electrode as a mask; and
removing the photoresist pattern that has been reduced to the second thickness.

2. The manufacturing method of the semiconductor device of claim 1, wherein the reducing the photoresist pattern to the second thickness comprises ashing the photoresist pattern.

3. The manufacturing method of the semiconductor device of claim 2, wherein, when ashing the photoresist pattern, the photoresist pattern is subjected to oxygen (O₂) plasma treatment or ozone (O₃) treatment.

4. The manufacturing method of the semiconductor device of claim 1, wherein the second thickness is 30% to 95% of the first thickness.

5. The manufacturing method of the semiconductor device of claim 4, wherein the first thickness and the second thickness are greater than a thickness of the gate electrode.

6. The manufacturing method of the semiconductor device of claim 1, wherein the removing the photoresist pattern that has been reduced to the second thickness comprises:
ashing the photoresist pattern; and
stripping the photoresist pattern.

7. The manufacturing method of the semiconductor device of claim 1, wherein forming the well region comprises implanting the first conductivity-type impurity ions at an angle of 10° or less with respect to a direction that is perpendicular to the front surface of the semiconductor substrate.

8. The manufacturing method of the semiconductor device of claim 1, wherein forming the halo region comprises implanting the low-concentration second conductivity-type impurity ions at an angle of 25° to 50° with respect to a direction that is perpendicular to the front surface of the semiconductor substrate.

9. The manufacturing method of the semiconductor device of claim 1, wherein the forming the photoresist pattern to the first thickness comprises:
depositing a photoresist layer to a thickness of 1.0 μm to 4 μm; and
patterning the photoresist layer.

10. The manufacturing method of the semiconductor device of claim 1, wherein the photoresist pattern that has been reduced to the second thickness has an inclined side surface.

11. The manufacturing method of the semiconductor device of claim 1, further comprising:
after the removing the photoresist pattern that has been reduced to the second thickness, forming a source region and a drain region by implanting the low-concentration second conductivity-type impurity ions into the front surface of the semiconductor substrate.

12. A manufacturing method of a semiconductor device, the manufacturing method comprising:
forming a photoresist pattern on a semiconductor substrate on which a gate electrode has been formed,
forming a well region using both the photoresist pattern and the gate electrode as a mask;
forming a lightly doped drain (LDD) region in the well region, using both the photoresist pattern and the gate electrode as the mask;
reducing a thickness of the photoresist pattern, by removing a portion of the photoresist pattern;
forming a halo region below the LDD region, using both the photoresist pattern and the gate electrode as the mask; and
removing the photoresist pattern.

13. The manufacturing method of the semiconductor device of claim 12,
wherein the forming the LDD region is performed before reducing the thickness of the photoresist pattern, or
wherein the reducing the thickness of the photoresist pattern is performed before forming the lightly doped drain (LDD) region.

14. The manufacturing method of the semiconductor device of claim 12,
wherein a portion of the LDD region overlaps the gate electrode.

15. The manufacturing method of the semiconductor device of claim 12,
wherein forming the well region comprises implanting first conductivity-type impurity ions in the semiconductor substrate,
wherein forming the LDD region comprises implanting second conductivity-type impurity ions in the semiconductor substrate, and
wherein forming the halo region comprises implanting first conductivity-type impurity ions in the semiconductor substrate.

16. The manufacturing method of the semiconductor device of claim 15, wherein forming the halo region comprises implanting the first conductivity-type impurity ions at an oblique angle with respect to a surface of the semiconductor substrate.

17. The manufacturing method of the semiconductor device of claim 15, further comprising:
after removing the photoresist pattern, forming a source region and a drain region by implanting second conductivity-type impurity ions in the well region.

18. The manufacturing method of the semiconductor device of claim 12, wherein reducing the thickness of the photoresist pattern comprises ashing the photoresist pattern.

19. A manufacturing method of a semiconductor device, the manufacturing method comprising:
forming a photoresist pattern to a first thickness on a semiconductor substrate on which a gate electrode has been formed;
forming a well region by implanting first conductivity-type impurity ions using both the photoresist pattern and the gate electrode as a mask;
forming a lightly doped drain (LDD) region by implanting second conductivity-type impurity ions in the well region using both the photoresist pattern and the gate electrode as the mask;
reducing a thickness of the photoresist pattern to a second thickness by removing a portion of the photoresist pattern;
forming a halo region below the LDD region by implanting the first conductivity-type impurity ions using both the photoresist pattern and the gate electrode as the mask; and
removing the photoresist pattern,
wherein the second thickness is 30% to 95% of the first thickness.

20. The manufacturing method of the semiconductor device of claim 19, wherein the first thickness is 1.0 μm to 4.0 μm.
